(19) United States
(12) Patent Application Publication
(10) Pub. No.: US 2017/0301431 A1
(43) Pub. Date: Oct. 19, 2017

(54) CABLE HAVING TWO INDIVIDUALLY INSULATED SIGNAL CORES

(71) Applicant: FOXCONN INTERCONNECT TECHNOLOGY LIMITED, Grand Cayman (KY)

(72) Inventors: JIAN LI, Kunshan (CN); HONG-PING WANG, Kunshan (CN); LU-YU CHANG, New Taipei (TW)

(21) Appl. No.: 15/487,447

(22) Filed: Apr. 14, 2017

(30) Foreign Application Priority Data
Apr. 14, 2016 (CN) 201620310965.5

(51) Int. Cl. H01B 7/02; H05K 9/00; H01B 11/00

(52) U.S. Cl. CPC H01B 7/02; H01B 11/005; H05K 9/0098

(57) ABSTRACT

A cable includes: a signal core module including a pair of inner conductors and an inner insulative layer enclosing the inner conductors, the inner conductors extending parallel to each other, the inner insulative layer forming a spacing region between said inner conductors; a grounding core arranged beside the signal core module; and a metal shielding layer enclosing the signal core module and the grounding core.

### BACKGROUND OF THE INVENTION

### 1. Field of the Invention

The present invention relates to a cable having a pair of individually insulated signal cores for transmission of high-speed signals.

### 2. Description of Related Arts

A high-speed signal cable typically includes a pair of signal cores, on or two ground wires, a metal shield around the cores and the ground wire or wires, and an insulated sheath outside the metal shield. Each of the pair of signal cores includes an inner insulating layer and an inner conductor coated by the inner insulating layer. The inner conductor and the inner insulation layer of each signal core are integrated with each other. The two signal cores are arranged side by side and wrapped in the metal shield.

U.S. Pat. No. 6,273,753, issued on Aug. 14, 2001, discloses a flat flexible cable assembly including a plurality of twins coaxial wires. Each wire includes two conductors, an insulating layer wrapping the two conductors, a metal braid covering the insulating layer, and a cable jacket.

U.S. Patent Application Publication No. 20150221415, published on Aug. 6, 2015, discloses a shielded electrical cable of which one exemplary embodiment shows a conductor set including two individually insulated conductors or two jointly insulated conductors.

### SUMMARY OF THE INVENTION

An object of the present invention is to provide a cable with a stable electrical properties.

To achieve the above-mentioned object, a cable comprises: a signal core module including a pair of inner conductors and an inner insulative layer enclosing the inner conductors, the inner conductors extending parallel to each other, the inner insulative layer forming a spacing region between said inner conductors; a grounding core arranged beside the signal core module; and a metal shielding layer enclosing the signal core module and the grounding core.

According to the present invention, the cable has a signal core module with an inner insulative layer one-time molded on the two inner conductor to have a stable electrical characteristic.

### BRIEF DESCRIPTION OF THE DRAWING

FIG. 1 is A schematic view of a high-speed signal cable in the prior art;

FIG. 2 is a schematic view of another high-speed signal cable in the prior art;

FIG. 3 is a schematic view of a cable in accordance with present invention; and

FIG. 4 is a schematic view of the signal core module of the cable as shown in FIG. 3.

### DETAILED DESCRIPTION OF THE PREFERRED EMBODIMENT

Reference will now be made in detail to a preferred embodiment of the present invention.

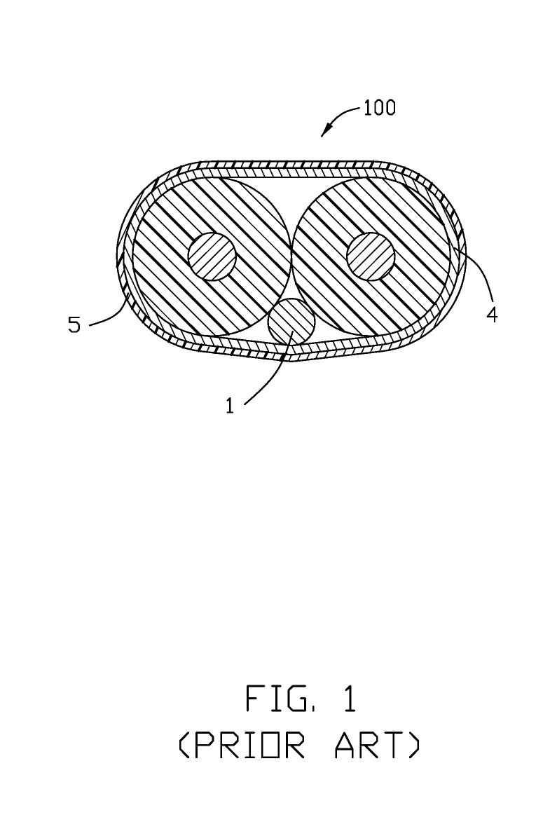

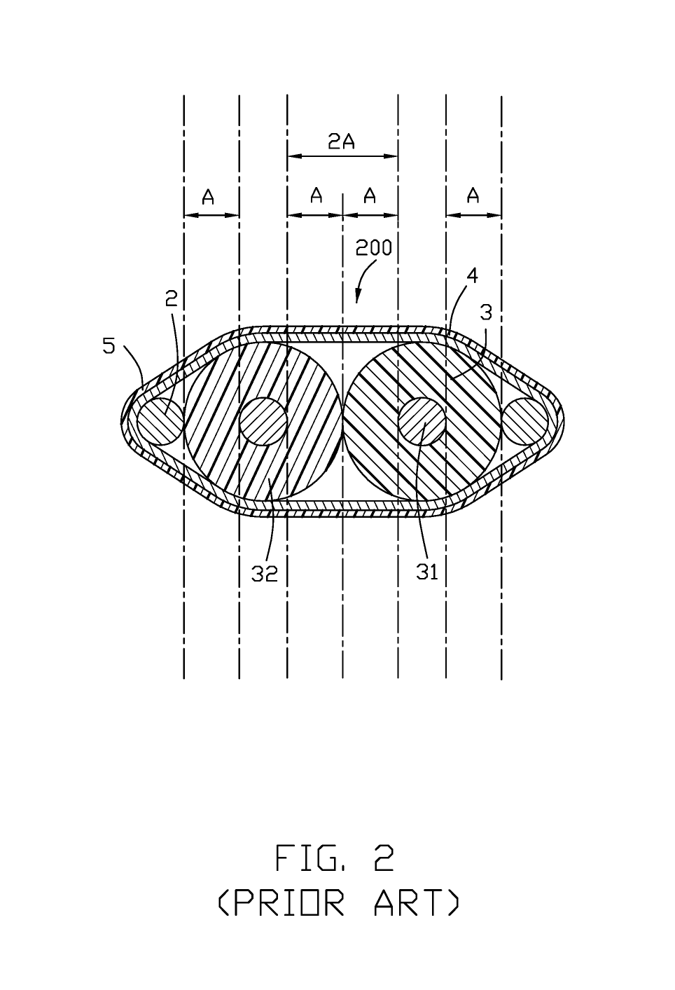

Referring to FIGS. 1 to 2, a high-speed signal cable 100 having a single grounding core 1 is shown in FIG. 1. A high-speed signal cable 200 having a pair of grounding cores 2 is shown in FIG. 2. Each of the high-speed signal cable 100 and the high-speed signal cable 200 includes a pair of signal cores 3 for transmitting differential signals, a metal shielding layer 5 enclosing the signal cores 3, and an outer insulative layer 6. Each of the signal cores 3 includes an inner conductor 31 and an inner insulative layer 32 enclosing the inner conductor 31. The two inner insulating layers 32 of the two signal cores 3 are respectively molded to cover the corresponding inner conductors 31.

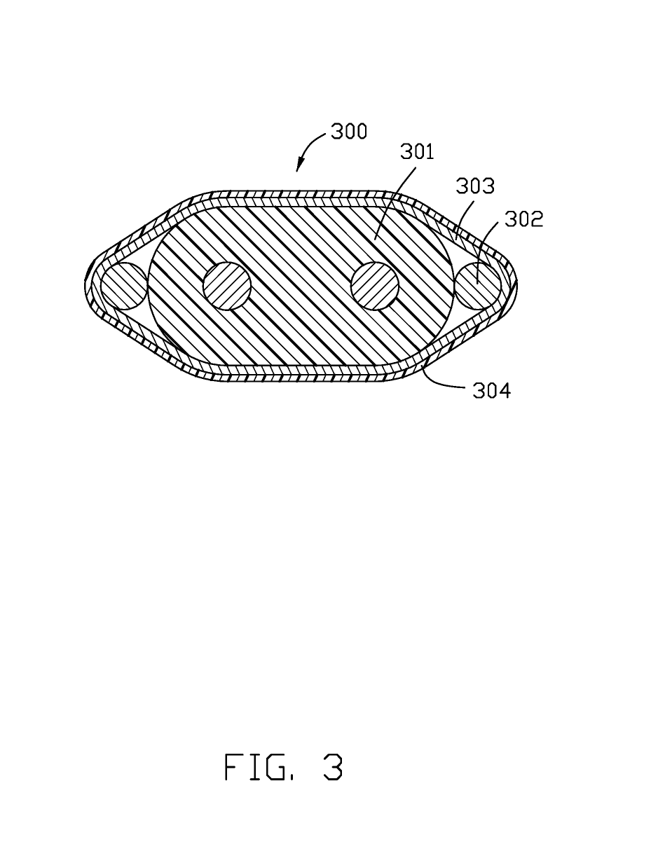

Referring to FIG. 3, a cable in accordance with a performed embodiment of the present invention includes a signal core module 301, a pair of grounding cores 302, a metal shielding layer 303 enclosing the signal core module 301 and the grounding cores 302 and a outer insulative housing 304 enclosing the metal shielding layer 303. The metal shielding layer 303 is made of aluminum foil material.

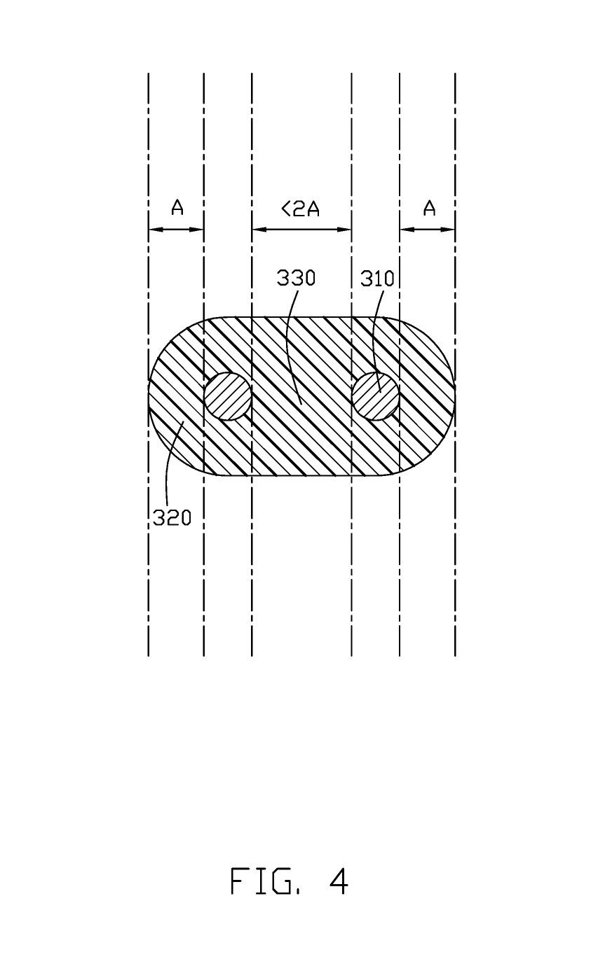

Referring to FIG. 4, the signal core module 301 includes a pair of inner conductors 310 side by side arranged with each other along a transverse direction and each extending along a front-to-back direction perpendicular to the transverse direction, and an inner insulative layer 320 formed at the periphery of the two inner conductors 310 in a molding, with the inner conductors 310 extend parallel to each other in the axial direction of the cable 300. The inner insulative layer 320 forms a spacing region 330 in a central area thereof between the inner conductors 310, and the spacing region 330 has a certain width between the inner conductors 310. The cross section of the signal core module 301 includes two parallel opposing straight edges, an arcuate edge connected between the ends of the same side of the two straight sides, and an arcuate edge connected between the ends of the opposite side of the two straight sides, and the combinations of the straight edges and the arcuate edges are over the smooth transition of its outer surface. The inner conductors 310 is a metallic material and may be a material such as copper or aluminum, and the inner insulating layer 320 may be made of an insulating material.

In the present embodiment, the cable 300 includes a pair of grounding cores 302, and each of them is arranged on two opposite sides of the signal core module 301 respectively, being arranged in a straight line in a radial direction of the cable 300. The distance of the pair of inner conductors 310 is basically equal to the distance of the grounding cores 302 from the inner conductors 310. The grounding cores 302 are electrically connected with the metal shielding layer 303, and then common ground. In other embodiments, the cable 300 may have one or more grounding cores 302, and the arrangement may also be adjusted as desired.

In the present embodiment, the distance between the left and right sides of the outer insulative layer 304 in a vertical direction is smaller than the distance from the middle portions of the outer insulative layer 304 in the vertical direction.

The two inner conductors 310 of the signal core module 301 of the utility model cable 300 are once formed within the unitary inner insulative layer 320, so that the process of the cable 300 is simplified and has a relatively stable electrical characteristic due to the relative positions of the inner conductors 310 are fixed, so that the cable 300 according to the present invention has a high degree of safety. On the other hand, once to unify the two respective insulative layers together, it may reduce the distance between the two inner conductors. For example, as shown in FIG. 2, in the conventional core module the inner insulative layer 32 may provide a thickness A to surround the corresponding inner conductor 31, thus resulting in a distance 2A between the two inner conductor 31. Differently, as shown in FIG. 4, in the invention, even though the inner insulative layer 320 provides a thickness A enclosing the transverse outer (one half) side of the corresponding inner conductor 310, i.e., the transverse outer 180-degree range with regard to the inner conductor 31, the distance between the two inner conductors 310 may be arranged/reduced to be less than 2A, thus minimizing the whole transverse dimension of the cable. It is noted that the cable defines a cross-sectional configuration essentially composed of a rectangular area with two opposite triangular areas symmetrically located at two opposite transverse sides of the, respectively, wherein the rectangular area is supportably filled with the insulative layer 320 while a space is formed between the inner insulative layer 320 and the grounding core 302 in the triangular area to confront the shielding layer 303. Generally speaking, the shielding layer 303 is intimately supported by the inner insulative layer 320 in the vertical direction perpendicular to both the transverse direction and the front-to-back direction, while being spaced from the inner insulative layer 320 in the transverse direction.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cable comprising:
a signal core module including a pair of inner conductors and an inner insulative layer directly and intimately enclosing the inner conductors, the inner conductors extending parallel to each other, the inner insulative layer forming a unitary spacing region between said inner conductors;
a grounding core arranged beside the signal core module; and
a metal shielding layer enclosing the signal core module and the grounding core.

2. The cable as recited in claim 1, wherein the inner insulative layer of the signal core module is molded on the periphery of the inner conductor.

3. The cable as recited in claim 2, wherein the outer surface of the signal core module is smoothly transitioned.

4. The cable as recited in claim 3, wherein a cross-section of the signal core module comprises two parallel opposite straight edges, an arcuate edge connected between the two ends on a same side of the two straight edges, and an arcuate edge connected between the two ends an opposite side of the two straight edges.

5. The cable as recited in claim 1, further comprising another grounding core arranged beside the signal core module and enclosed by the metal shielding layer.

6. The cable as recited in claim 5, wherein one of the grounding cores is arranged on a side of the signal core module, and another of the grounding core is arranged on an opposite side of the signal core module.

7. The multiplexing device as recited in claim 6, wherein the inner conductors and the ground cores are arranged in a straight line.

8. The cable as recited in claim 5, further comprising an outer insulative layer enclosing the metal shielding layer.

9. A cable comprising:
a signal core module including a pair of inner conductors side by side arranged with each other in a transverse direction, each of said inner conductors extending along a front-to-back direction perpendicular to said transverse direction and forming a circular cross-section, a unitary inner insulative layer enclosing both said pair of inner conductors;
a pair of grounding cores intimately disposed by two outer transverse sides of said inner insulative layer; and
a metal shielding layer enclosing both said signal core module and said pair of grounding cores.

10. The cable as claimed in claim 9, wherein said insulative layer forms a cross-sectional racecourse configuration to enclose the pair of inner conductors.

11. The cable as claimed in claim 10, wherein the insulative layer provide a thickness having a dimension of “A” on a transverse outer side of the corresponding inner conductor while a distance between the pair of inner conductor is smaller than 2A.

12. The cable as claimed in claim 9, wherein the cable defines a cross-sectional configuration essentially composed of a rectangular area with two opposite triangular areas symmetrically located at two opposite transverse sides of the, respectively.

13. The cable as claimed in claim 12, wherein the rectangular area is supportably filled with the insulative layer while a space is formed between the insulative layer and the grounding core in the triangular area to confront the shielding layer.

14. The cable as claimed in claim 9, further including an outer insulative layer intimately enclosing the metal shielding layer.

15. A cable comprising:
a signal core module including a pair of inner conductors side by side arranged with each other in a transverse direction, each of said inner conductors extending along a front-to-back direction perpendicular to said transverse direction and forming a circular cross-section, a unitary inner insulative layer enclosing both said pair of inner conductors; wherein
said insulative layer forms a cross-sectional racecourse configuration to enclose the pair of inner conductors.

16. The cable as claimed in claim 15, wherein the insulative layer provide a thickness having a dimension of “A” on a transverse outer side of the corresponding inner conductor while a distance between the pair of inner conductor is smaller than 2A.

17. The cable as claimed in claim 15, further including a metal shielding layer enclosing said signal core module, wherein said shielding layer is intimately supported by the insulative layer in a vertical direction perpendicular to both said transverse direction and said front-to-back direction while be spaced from the insulative layer in the transverse direction.

18. The cable as claimed in claim 17, wherein a pair of grounding cores are disposed by two transverse sides of the inner insulative layer in said transverse direction and sandwiched between the shielding layer and the inner insulative layer in said transverse direction.

19. The cable as claimed in claim 18, wherein the cable defines a cross-sectional configuration essentially composed of a rectangular area with two triangular areas by two transverse sides of the inner insulative layer.
